(19) United States
(12) Patent Application Publication
(10) Pub. No.: US 2022/0163571 A1
(43) Pub. Date: May 26, 2022

(54) CURRENT SENSOR

(71) Applicant: Murata Manufacturing Co., Ltd., Nagaokakyo-shi (JP)

(72) Inventor: Yoshihiro ITO, Nagaokakyo-shi (JP)

(21) Appl. No.: 17/666,599

(22) Filed: Feb. 8, 2022

Related U.S. Application Data
(63) Continuation of application No. PCT/JP2020/029224, filed on Jul. 30, 2020.

(30) Foreign Application Priority Data
Aug. 26, 2019 (JP) 2019-153424

(51) Int. Cl. G01R 15/20; H01L 23/31; H01L 23/495

(52) U.S. Cl. CPC G01R 15/207; G01R 15/205; H01L 23/49579; H01L 23/49558; H01L 23/3121

(57) ABSTRACT

A magnetic sensor chip includes a magnetic sensor including a magneto-resistance element and connection terminals electrically connected to the magnetic sensor. Signal terminals are separated from the current path and are electrically connected to the connection terminals by bonding wires. A support is separated from the current path, is at a different potential from the current path, and supports the magnetic sensor chip. The magnetic sensor chip is at a position overlapping the current path when viewed in a direction in which the magnetic sensor chip and the support are arrayed.

### CROSS REFERENCE TO RELATED APPLICATIONS

This application claims the benefit of priority to Japanese Patent Application No. 2019-153424 filed on Aug. 26, 2019 and is a Continuation Application of PCT Application No. PCT/JP2020/029224 filed on Jul. 30, 2020. The entire contents of each application are hereby incorporated herein by reference.

### BACKGROUND OF THE INVENTION

### 1. Field of the Invention

The present invention relates to a current sensor.

### 2. Description of the Related Art

Related art documents disclosing the configuration of a current sensor include Japanese Unexamined Patent Application Publication No. 2018-179994, Japanese Unexamined Patent Application Publication No. 2013-79973, and Japanese Unexamined Patent Application Publication No. 2017-49264.

The current sensor described in Japanese Unexamined Patent Application Publication No. 2018-179994 includes a conductor along which a current to be measured flows, a magnetic sensor that detects a magnetic field generated by the current flowing along the conductor, and a package that separates the magnetic sensor from the conductor and covers and seals the outer surfaces of the magnetic sensor and at least a portion of the conductor. The magnetic sensor includes a Hall element or a magneto-resistance element. In plan view, the magnetic sensor is disposed inside a curved portion of the conductor so as to be spaced apart from the curved portion.

The current sensor described in Japanese Unexamined Patent Application Publication No. 2013-79973 includes a lead frame having at least two leads that are coupled to form a conductor portion and a substrate having a first surface on which a magnetic field transducer is disposed, the first surface being near the conductor portion and a second surface of the substrate being distant from the conductor portion. The substrate contacts the lead frame via an insulator. The magnetic field transducer is a Hall element. In other words, the magnetic field transducer is a magnetic sensor.

The current sensor described in Japanese Unexamined Patent Application Publication No. 2017-49264 includes a lead frame and a die. The lead frame has a first portion including current leads connected so as to form a current conductor for transporting a primary current and a second portion including signal leads. The die is coupled to a second lead frame portion by an interconnection. The die provides a magnetic field sensing circuit that senses the magnetic field related to the primary current and generates an output in one of the signal leads based on the sensed magnetic field. The interconnection is achieved with a flip chip method using solder bumps. The magnetic field sensing circuit includes a magnetic field transducer that has a sensing element selected from one of a Hall-effect sensing element or a magneto-resistance sensing element. In other words, the magnetic field transducer is a magnetic sensor.

In the current sensor described in Japanese Unexamined Patent Application Publication No. 2018-179994, since the magnetic sensor is disposed inside the curved portion of the conductor, there is room to improve the magnetic field detection characteristics of the magnetic sensor if the magnetic sensor includes a magneto-resistance element.

In the current sensor described in Japanese Unexamined

Patent Application Publication No. 2013-79973, the substrate is in contact with the lead frame through an insulator, and therefore the dielectric strength characteristics of the magnetic sensor located on the substrate may be degraded when a surface discharge occurs between the substrate and the insulator.

In the current sensor described in Japanese Unexamined Patent Application Publication No. 2017-49264, the die provided with the magnetic sensor is connected to the signal leads using a flip chip method, and therefore the magnetic field detection characteristics of the magnetic sensor become unstable due to the strain transmitted to the magnetic sensor through the signal leads.

### SUMMARY OF THE INVENTION

Preferred embodiments of the present invention provide current sensors that are each able to stabilize magnetic field detection characteristics while improving dielectric strength characteristics.

A current sensor according to a preferred embodiment of the present invention includes a current path, a magnetic sensor chip, a plurality of signal terminals, and a support. A current to be measured flows along the current path. The magnetic sensor chip includes at least one magnetic sensor including a magneto-resistance element and a plurality of connection terminals electrically connected to the at least one magnetic sensor. The plurality of signal terminals are separated from the current path and are electrically connected to the plurality of connection terminals by bonding wires. The support is separated from the current path, is at a different potential from the current path, and supports the magnetic sensor chip. The at least one magnetic sensor is at a position overlapping the current path when viewed in a direction in which the magnetic sensor chip and the support are arrayed.

According to preferred embodiments of the present invention, magnetic field detection characteristics are able to be stabilized while improving dielectric strength characteristics.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a perspective view illustrating the configuration of a current sensor according to Preferred Embodiment 1 of the present invention.

FIG. 2 is a sectional view in which the current sensor in FIG. 1 is viewed in the direction of arrows II-II.

FIG. 3 is a plan view in which the current sensor in FIG. 2 is viewed in the direction of arrow III.

FIG. 4 is a plan view illustrating the configuration of magnetic sensors of the current sensor of Preferred Embodiment 1 of the present invention.

FIG. 5 is a perspective view illustrating the configuration of a current sensor according to Preferred Embodiment 2 of the present invention.

FIG. 6 is a sectional view illustrating the configuration of a current sensor according to Preferred Embodiment 3 of the present invention.

FIG. 7 is a plan view in which the current sensor in FIG. 6 is viewed in the direction of arrow VII.

FIG. 8 is a sectional view illustrating the configuration of a current sensor according to a modification of Preferred Embodiment 3 of the present invention.

FIG. 9 is a plan view in which the current sensor in FIG. 7 is viewed in the direction of arrow IX.

FIG. 10 is a perspective view illustrating the configuration of a current sensor according to Preferred Embodiment 4 of the present invention.

FIG. 11 is a sectional view in which the current sensor in FIG. 10 is viewed in the direction of arrows XI-XI.

FIG. 12 is a plan view in which the current sensor in FIG. 11 is viewed in the direction of arrow XII.

FIG. 13 is a perspective view illustrating the configuration of a current sensor according to a modification of Preferred Embodiment 4 of the present invention.

FIG. 14 is a sectional view in which the current sensor in FIG. 13 is viewed in the direction of arrows XIV-XIV.

FIG. 15 is a plan view in which the current sensor in FIG. 14 is viewed in the direction of arrow XV.

FIG. 16 is a perspective view illustrating the configuration of a current sensor according to Preferred Embodiment 5 of the present invention.

FIG. 17 is a sectional view in which the current sensor in FIG. 16 is viewed in the direction of arrows XVII-XVII.

FIG. 18 is a plan view in which the current sensor in FIG. 17 is viewed in the direction of arrow XVIII.

### DETAILED DESCRIPTION OF THE PREFERRED EMBODIMENTS

Hereafter, current sensors according to preferred embodiments of the present invention will be described with reference to the drawings. In the following description of the preferred embodiments, the same or corresponding portions in the drawings are denoted by the same symbols and repeated description thereof is omitted.

### Preferred Embodiment 1

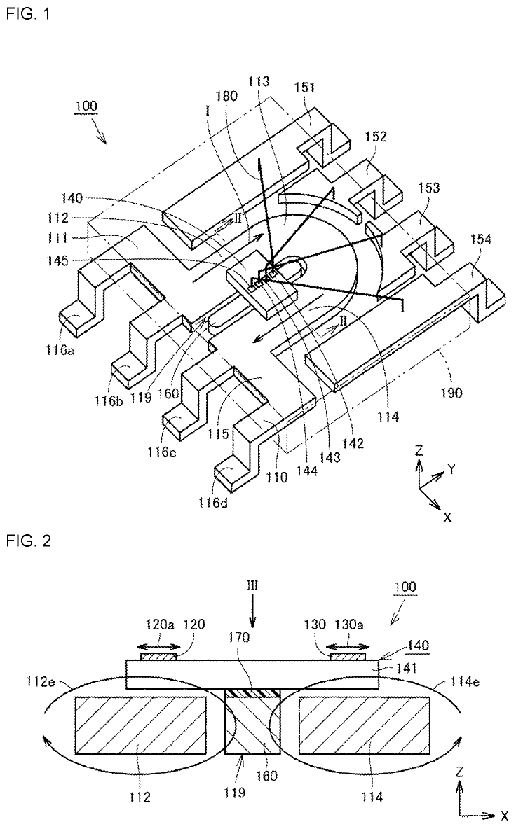

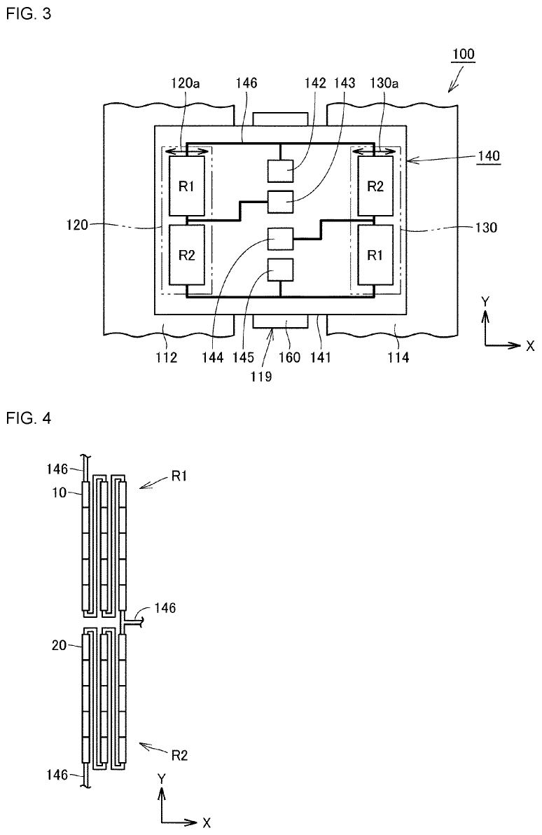

FIG. 1 is a perspective view illustrating the configuration of a current sensor according to Preferred Embodiment 1 of the present invention. FIG. 2 is a sectional view in which the current sensor in FIG. 1 is viewed in the direction of arrows II-II. FIG. 3 is a plan view in which the current sensor in FIG. 2 is viewed in the direction of arrow III. In FIG. 1, sealing resin is illustrated in a see-through manner. The sealing resin is not illustrated in FIGS. 2 and 3. In the following description, a length direction of the current sensor is an X-axis direction, a width direction of the current sensor is a Y-axis direction, and a thickness direction of the current sensor is a Z-axis direction.

As illustrated in FIGS. 1 to 3, a current sensor 100 according to Preferred Embodiment 1 of the present invention includes a current path 110, a magnetic sensor chip 140, a plurality of signal terminals, and a support 160. In Preferred Embodiment 1 of the present invention, the current sensor 100 includes a first signal terminal 151, a second signal terminal 152, a third signal terminal 153, and a fourth signal terminal 154. However, the number of signal terminals is not limited to four as long as there are a plurality of signal terminals.

As illustrated in FIG. 1, a current I that is to be measured flows along the current path 110. In Preferred Embodiment 1 of the present invention, the current path 110 includes a U-shaped folded-back portion. The shape of the folded-back portion may instead be a V shape or a semi-circular shape, for example.

Specifically, the current path 110 includes a first current path portion 111 that extends towards one side in the X-axis direction, a second current path portion 112 that extends towards one side in the Y-axis direction from an end portion of the first current path portion 111 on the one side in the X-axis direction, a third current path portion 113 that extends from an end portion of the second current path portion 112 on the one side in the Y-axis direction and curves in a semi-circular shape when seen in the Z-axis direction, a fourth current path portion 114 that extends towards the other side in the Y-axis direction from an end portion of the third current path portion 113, and a fifth current path portion 115 that extends from an end portion of the fourth current path portion 114 on the other side in the Y-axis direction towards the one side in the X-axis direction.

The second current path portion 112 and the fourth current path portion 114 define a pair of opposing portions that are positioned with a gap 119 therebetween and in which the current I flows in opposite directions. One of the pair of opposing portions is the second current path portion 112 and the other of the pair of opposing portions is the fourth current path portion 114.

The first current path portion 111, the second current path portion 112, the third current path portion 113, the fourth current path portion 114, and the fifth current path portion 115 are embedded in a sealing resin 190. The sealing resin 190 is an insulating resin such as epoxy resin, for example.

The current path 110 further includes a first current terminal 116a, a second current terminal 116b, a third current terminal 116c, and a fourth current terminal 116d, which are arrayed with spaces therebetween in the X-axis direction. The first current terminal 116a is connected to a portion of the first current path portion 111 on the other side in the X-axis direction. The second current terminal 116b is connected to a portion of the first current path portion 111 on the one side in the X-axis direction. The third current terminal 116c is connected to a portion of the fourth current path portion 114 on the other side in the X-axis direction. The fourth current terminal 116d is connected to a portion of the fourth current path portion 114 on the one side in the X-axis direction.

Portions of the first current terminal 116a, the second current terminal 116b, the third current terminal 116c, and the fourth current terminal 116d other than the end portions on the one side in the Y-axis direction are not covered by the sealing resin 190 and are exposed.

The current path 110 is made of a material having low electrical resistivity such as copper, for example. In Preferred Embodiment 1 of the present invention, the current path 110 is formed using press molding, for example. The current path 110 may instead be formed using, for example, etching, sintering, forging, cutting, or another method.

As illustrated in FIG. 1, the first signal terminal 151, the second signal terminal 152, the third signal terminal 153, and the fourth signal terminal 154 are separated from the current path 110. The first signal terminal 151, the second signal terminal 152, the third signal terminal 153, and the fourth signal terminal 154 are disposed in order with spaces therebetween towards the one side in the X-axis direction. The first signal terminal 151, the second signal terminal 152, the third signal terminal 153, and the fourth signal terminal 154 extend towards the one side in the Y-axis direction. The end portions of the first signal terminal 151, the second signal terminal 152, the third signal terminal 153, and the fourth signal terminal 154 on the one side in the Y-axis direction are not covered by the sealing resin 190 and are exposed, and the remaining portions thereof are embedded in the sealing resin 190. The first to fourth signal terminals 151 to 154 are insulated from the current path 110 by the sealing resin 190.

In Preferred Embodiment 1 of the present invention, the surfaces, on one side in the Z-axis direction, of the portions of the first signal terminal 151, the second signal terminal 152, the third signal terminal 153, and the fourth signal terminal 154 that are embedded in the sealing resin 190 and the surfaces, on the one side in the Z-axis direction, of the first current path portion 111, the second current path portion 112, the third current path portion 113, the fourth current path portion 114, and the fifth current path portion 115 are located on the same or substantially the same plane. However, they do not necessarily have to be located on the same or substantially the same plane.

The first to fourth signal terminals 151 to 154 are made of a material having low electrical resistivity such as copper, for example. In Preferred Embodiment 1 of the present invention, the first to fourth signal terminals 151 to 154 are formed using press molding, for example. The first to fourth signal terminals 151 to 154 may instead be formed using etching, sintering, forging, cutting, or another method, for example.

As illustrated in FIGS. 1 to 3, the support 160 is spaced apart from the current path 110. The support 160 is disposed in the gap 119. The support 160 extends towards the one side in the Y-axis direction. Therefore, the support 160 is located between the second current path portion 112 and the fourth current path portion 114. The support 160 is embedded in the sealing resin 190. The support 160 is in a floating potential state and has a different potential from the current path 110. The support 160 and the current path 110 are insulated from each other by the sealing resin 190.

In Preferred Embodiment 1 of the present invention, as illustrated in FIGS. 1 and 2, the surface of the support 160 on the one side in the Z-axis direction and the surfaces of the second current path portion 112 and the fourth current path portion 114 on the one side in the Z-axis direction are located on the same or substantially the same plane. However, the surface of the support 160 on the one side in the Z-axis direction and the surfaces of the second current path portion 112 and the fourth current path portion 114 on the one side in the Z-axis direction do not necessarily have to be located on the same or substantially the same plane.

The support 160 is made of a material having low electrical resistivity such as copper, for example. In Preferred Embodiment 1 of the present invention, the support 160 is formed using press molding, for example. The support 160 may instead be formed using etching, sintering, forging, cutting, or another method, for example.

In Preferred Embodiment 1 of the present invention, the current path 110, the first to fourth signal terminals 151 to 154, and the support 160 are formed by pressing a single sheet of sheet metal and are therefore formed from a single member. However, the current path 110, the first to fourth signal terminals 151 to 154, and the support 160 may instead be individually provided as different members.

As illustrated in FIGS. 2 and 3, the magnetic sensor chip 140 includes a substrate 141. In Preferred Embodiment 1 of the present invention, the substrate 141 is made of silicon, for example. However, the material of the substrate 141 does not have to be silicon and may instead be another semiconductor or an insulator, for example.

As illustrated in FIGS. 1 to 3, the magnetic sensor chip 140 includes at least one magnetic sensor including a magneto-resistance element and detects the strength of a magnetic field generated by the current I flowing along the current path 110 and includes a plurality of connection terminals that are electrically connected to the at least one magnetic sensor.

As illustrated in FIGS. 2 and 3, in the current sensor 100 according to Preferred Embodiment 1 of the present invention, the magnetic sensor chip 140 includes a first magnetic sensor 120 and a second magnetic sensor 130 as the at least one magnetic sensor. The first magnetic sensor 120 and the second magnetic sensor 130 are provided on the substrate 141. In Preferred Embodiment 1 of the present invention, the number of magnetic sensors is not limited to two as long as there are a plurality of magnetic sensors.

As illustrated in FIGS. 2 and 3, a magnetic sensitivity axis 120a of the first magnetic sensor 120 extends along the X-axis direction. A magnetic sensitivity axis 130a of the second magnetic sensor 130 extends along the X-axis direction. As illustrated in FIG. 3, the first magnetic sensor 120 and the second magnetic sensor 130 each include a bridge circuit including a magneto-sensitive resistance R1 and a fixed resistance R2. The resistance value of the magneto-sensitive resistance R1 changes when a magnetic field along the X-axis direction is applied thereto. The resistance value of the fixed resistance R2 negligibly changes even when a magnetic field along the X-axis direction is applied thereto.

FIG. 4 is a plan view illustrating the configuration of the magnetic sensors of the current sensor of Preferred Embodiment of the present invention. In Preferred Embodiment 1 of the present invention, the first magnetic sensor 120 and the second magnetic sensor 130 include tunnel magneto-resistance (TMR) elements as magneto-resistance elements. As illustrated in FIG. 4, in the magneto-sensitive resistance R1, a magneto-sensitive element series 10 is provided in which a plurality of TMR elements are connected in series with each other. In the fixed resistance R2, a reference element series 20 is provided in which a plurality of TMR elements are connected in series with each other. A shielding structure, which is not illustrated, covers the reference element series 20. Magnetic fields are blocked by the shielding structure and therefore no or substantially no magnetic field is applied to the TMR elements of the reference element series 20.

Note that the first magnetic sensor 120 and the second magnetic sensor 130 may include giant magneto-resistance (GMR) elements or anisotropic magneto-resistance (AMR) elements as magneto-resistance elements instead of the TMR elements.

As illustrated in FIGS. 1 to 3, the support 160 supports the magnetic sensor chip 140. In Preferred Embodiment 1 of the present invention, the magnetic sensor chip 140 is supported by the support 160 by the surface of the support 160 on the one side in the Z-axis direction and the surface of the substrate 141 on the other side in the Z-axis direction being connected to each other by a die attach film 170. The member connecting the support 160 and the magnetic sensor chip 140 to each other does not have to be the die attach film 170 and may instead be an adhesive, for example. In Preferred Embodiment 1 of the present invention, since the support 160 is in a floating potential state, the die attach film 170 may be either electrically conductive or electrically insulating. The area of the die attach film 170 is preferably less than or equal to the area of the surface of the support 160 on the one side in the Z-axis direction.

As illustrated in FIG. 2, when the magnetic sensor chip 140 is supported by the support 160, the surface of the substrate 141 on the other side in the Z-axis direction and the surfaces of the second current path portion 112 and the fourth current path portion 114 on the one side in the Z-axis direction are separated from each other. Note that the surface of the substrate 141 on the other side in the Z-axis direction defines a surface of the magnetic sensor chip 140 on the other side in the Z-axis direction.

Therefore, the die attach film 170 will be thicker where the surface of the support 160 on the one side in the Z-axis direction is located closer to the other side in the Z-axis direction than the surfaces of the second current path portion 112 and the fourth current path portion 114 on the one side in the Z-axis direction compared to a case where these surfaces are located on the same or substantially the same plane.

As illustrated in FIG. 3, the at least one magnetic sensor is disposed at a position overlapping the current path 110 when viewed in the Z-axis direction, which is the direction in which the magnetic sensor chip 140 and the support 160 are arrayed. In Preferred Embodiment 1 of the present invention, viewed in the Z-axis direction, the first magnetic sensor 120 is disposed at a position overlapping the second current path portion 112 and the second magnetic sensor 130 is disposed at a position overlapping the fourth current path portion 114.

As illustrated in FIG. 2, with this arrangement, when the current I flows along the current path 110, a magnetic field 112e generated around the second current path portion 112 acts on the first magnetic sensor 120 in a direction along the magnetic sensitivity axis 120a and a magnetic field 114e generated around the fourth current path portion 114 acts on the second magnetic sensor 130 in a direction along the magnetic sensitivity axis 130a.

The magnetic sensor chip 140 includes a first connection terminal 142, a second connection terminal 143, a third connection terminal 144, and a fourth connection terminal 145, which are electrically connected to the first magnetic sensor 120 and the second magnetic sensor 130 by wiring lines 146.

Specifically, the first connection terminal 142 is a power supply terminal Vcc connected to a power supply and is connected to the magneto-sensitive resistance R1 of the first magnetic sensor 120 and the fixed resistance R2 of the second magnetic sensor 130. The fourth connection terminal 145 is a ground terminal GND that is at the ground potential and is connected to the fixed resistance R2 of the first magnetic sensor 120 and the magneto-sensitive resistance R1 of the second magnetic sensor 130.

The second connection terminal 143 is an output terminal V+of the first magnetic sensor 120 and is connected to a center point between the magneto-sensitive resistance R1 and the fixed resistance R2 of the first magnetic sensor 120. The third connection terminal 144 is an output terminal V- of the second magnetic sensor 130 and is connected to a center point between the fixed resistance R2 and the magneto-sensitive resistance R1 of the second magnetic sensor 130.

The first connection terminal 142, the second connection terminal 143, the third connection terminal 144, and the fourth connection terminal 145 are disposed at positions overlapping the support 160 when viewed in the Z-axis direction, which is the direction in which the magnetic sensor chip 140 and the support 160 are arrayed.

As illustrated in FIG. 1, the first signal terminal 151 and the first connection terminal 142 are electrically connected to each other by a bonding wire 180, the second signal terminal 152 and the second connection terminal 143 are electrically connected to each other by a bonding wire 180, the third signal terminal 153 and the third connection terminal 144 are electrically connected to each other by a bonding wire 180, and the fourth signal terminal 154 and the fourth connection terminal 145 are electrically connected to each other by a bonding wire 180.

The magnetic sensor chip 140 and the bonding wires 180 are embedded in the sealing resin 190. Therefore, the magnetic sensor chip 140 and the current path 110 are insulated from each other by the sealing resin 190.

Hereafter, operation of the current sensor 100 according to Preferred Embodiment 1 of the present invention will be described.

As illustrated in FIG. 1, the current I that is to be measured flows along the second current path portion 112 towards the one side in the Y-axis direction and flows along the fourth current path portion 114 towards the other side in the Y-axis direction. Therefore, as illustrated in FIG. 2, the magnetic field 112e, which is generated as a result of the current I that is to be measured flowing along the second current path portion 112, acts on the first magnetic sensor 120 in a direction towards the other side in the X-axis direction. On the other hand, the magnetic field 114e, which is generated as a result of the current I that is to be measured flowing along the fourth current path portion 114, acts on the second magnetic sensor 130 in a direction towards the one side in the X-axis direction.

Therefore, the values of the strength of the magnetic field generated by the current I that is to be measured flowing along the current path 110 detected by the first magnetic sensor 120 and detected by the second magnetic sensor 130 have opposite phases from each other. Therefore, when the strength of the magnetic field detected by the first magnetic sensor 120 is a positive value, the strength of the magnetic field detected by the second magnetic sensor 130 is a negative value. The current I that is to be measured flowing along the current path 110 can be calculated while canceling out the effect of external magnetic fields by processing the values detected by the first magnetic sensor 120 and the values detected by the second magnetic sensor 130 using a differential amplification circuit.

In the current sensor 100 according to Preferred Embodiment 1 of the present invention, since the support 160, which supports the magnetic sensor chip 140, is spaced apart from the current path 110 and is at a different potential from the current path 110 and there are no interfaces connecting the first magnetic sensor 120 and the second magnetic sensor 130 and the current path 110 to each other, the generation of surface discharge between the current path 110 and the magnetic sensor chip 140 can be reduced or prevented and the dielectric strength characteristics of the current sensor 100 can be improved.

Furthermore, in the current sensor 100 according to Preferred Embodiment 1 of the present invention, the first magnetic sensor 120 is disposed at a position overlapping the second current path portion 112 and the second magnetic sensor 130 is disposed at a position overlapping the fourth current path portion 114 when viewed in the Z-axis direction, which is the direction in which the magnetic sensor chip 140 and the support 160 are arrayed.

Thus, the magnetic field 112e generated around the second current path portion 112 acts on the first magnetic sensor 120 in a direction along the magnetic sensitivity axis 120a and the magnetic field 114e generated around the fourth current path portion 114 acts on the second magnetic sensor 130 in a direction along the magnetic sensitivity axis 130a. As a result, the current I that is to be measured flowing along the current path 110 can be detected with high sensitivity by the first magnetic sensor 120 and the second magnetic sensor 130.

Furthermore, in the current sensor 100 according to Preferred Embodiment 1 of the present invention, the first signal terminal 151 and the first connection terminal 142 are electrically connected to each other by the bonding wire 180, the second signal terminal 152 and the second connection terminal 143 are electrically connected to each other by the bonding wire 180, the third signal terminal 153 and the third connection terminal 144 are electrically connected to each other by the bonding wire 180, and the fourth signal terminal 154 and the fourth connection terminal 145 are electrically connected to each other by the bonding wire 180, and therefore the transmission of strain from the first to fourth signal terminals 151 to 154 to the first magnetic sensor 120 and the second magnetic sensor 130 can be reduced or prevented. Therefore, it is possible to reduce or prevent a situation in which the magnetic field detection characteristics of the first magnetic sensor 120 and the second magnetic sensor 130 become unstable due strain transmitted from the first to fourth signal terminals 151 to 154.

As a result of the current sensor 100 according to Preferred Embodiment 1 of the present invention having the above-described configuration, the magnetic field detection characteristics of the first magnetic sensor 120 and the second magnetic sensor 130 can be stabilized while improving the dielectric strength characteristics of the current sensor 100.

In the current sensor 100 according to Preferred Embodiment 1 of the present invention, the current path 110 includes a pair of opposing portions that are positioned with the gap 119 therebetween and in which the current I to be measured flows in opposite directions, and the first magnetic sensor 120 is disposed at a position overlapping the second current path portion 112, which is one of the pair of opposing portions, and the second magnetic sensor 130 is disposed at a position overlapping the fourth current path portion 114, which is the other one of the pair of opposing portions, when viewed in the direction in which the magnetic sensor chip 140 and the support 160 are arrayed.

As a result, since the values of the strength of the magnetic field generated by the current I that is to be measured flowing along the current path 110 detected by the first magnetic sensor 120 and detected by the second magnetic sensor 130 have opposite phases from each other, the current I that is to be measured flowing along the current path 110 can be detected with high sensitivity while canceling out the effect of external magnetic fields by processing the values detected the first magnetic sensor 120 and the values detected by the second magnetic sensor 130 using a differential amplification circuit.

In the current sensor 100 according to Preferred

Embodiment 1 of the present invention, the support 160 is disposed in the gap 119. This enables the dielectric strength characteristics of the current sensor 100 to be improved without increasing the size of the current sensor 100.

In the current sensor 100 according to Preferred Embodiment 1 of the present invention, the current path 110, the first to fourth signal terminals 151 to 154, and the support 160 are defined by a single member. This allows the current path 110, the first to fourth signal terminals 151 to 154, and the support 160 to be easily formed using a method such as, for example, pressing a single sheet of sheet metal while maintaining stable characteristics.

In the current sensor 100 according to Preferred Embodiment 1 of the present invention, the first to fourth connection terminals 142 to 145 are disposed at positions overlapping the support 160 when viewed in the Z-axis direction, which is the direction in which the magnetic sensor chip 140 and the support 160 are arrayed. Thus, the magnetic sensor chip 140 can be supported by the support 160 at the surface of the substrate 141 on the other side in the Z-axis direction, which is the surface of the substrate 141 on the opposite side from the surface of the substrate 141 on the one side in the Z-axis direction where the first to fourth connection terminals 142 to 145 are provided, and therefore the bonding wires 180 can be firmly connected to the first to fourth connection terminals 142 to 145. As a result, the reliability of the electrical connections between the first to fourth connection terminals 142 to 145 and the magnetic sensor chip 140 can be improved.

Preferred Embodiment 2

Hereafter, a current sensor according to Preferred Embodiment 2 of the present invention will be described with reference to the drawings. The current sensor according to Preferred Embodiment 2 of the present invention differs from the current sensor 100 according to Preferred Embodiment 1 of the present invention mainly with respect to the numbers of current terminals and signal terminals, and therefore description of the portions of the configuration that are the same or substantially the same as the current sensor 100 according to Preferred Embodiment 1 of the present invention will not be repeated.

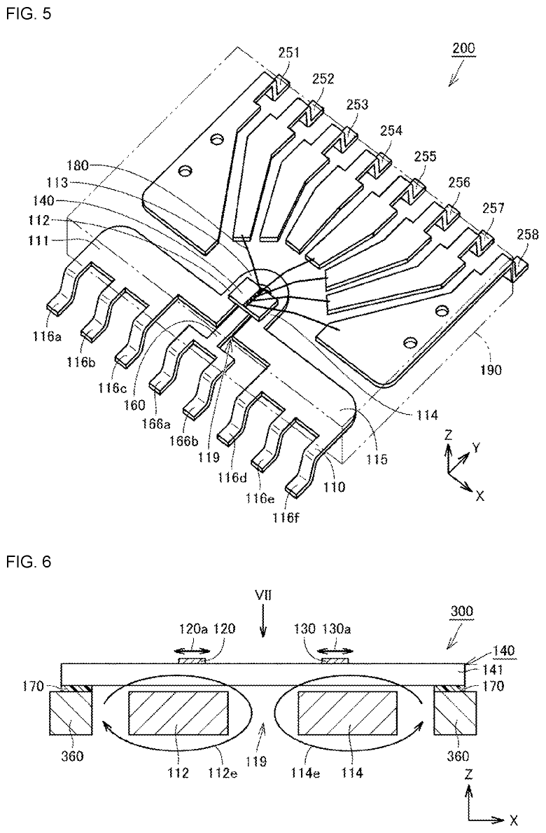

FIG. 5 is a perspective view illustrating the configuration of the current sensor according to Preferred Embodiment 2 of the present invention. In FIG. 5, sealing resin is illustrated in a see-through manner. As illustrated in FIG. 5, a current sensor 200 according to Preferred Embodiment 2 of the present invention includes a first signal terminal 251, a second signal terminal 252, a third signal terminal 253, a fourth signal terminal 254, a fifth signal terminal 255, a sixth signal terminal 256, a seventh signal terminal 257, and an eighth signal terminal 258.

In the current sensor 200 according to Preferred Embodiment 2 of the present invention, the current path 110 includes a first current terminal 116a, a second current terminal 116b, a third current terminal 116c, a fourth current terminal 116d, a fifth current terminal 116e, and a sixth current terminal 116f, which are arrayed in the X-axis direction with spaces therebetween.

The first current terminal 116a is connected to a portion of the first current path portion 111 on the other side in the X-axis direction. The second current terminal 116b is connected to a portion of the first current path portion 111 at the center or approximate center in the X-axis direction. The third current terminal 116c is connected to a portion of the first current path portion 111 on the one side in the X-axis direction. The fourth current terminal 116d is connected to a portion of the fifth current path portion 115 on the other side in the X-axis direction. The fifth current terminal 116e is connected to a portion of the fifth current path portion 115 at the center or approximate center in the X-axis direction. The sixth current terminal 116f is connected to a portion of the fifth current path portion 115 on the one side in the X-axis direction.

The support 160 further includes a first support terminal 166a and a second support terminal 166b, which are not covered by the sealing resin 190 and are exposed. The first support terminal 166a and the second support terminal 166b are positioned with a space therebetween in the X-axis direction. The first support terminal 166a and the second support terminal 166b are disposed between the third current terminal 116c and the fourth current terminal 116d in the X-axis direction.

In the current sensor 200 according to Preferred Embodiment 2 of the present invention, the magnetic sensor chip 140 includes five connection terminals. The five connection terminals are respectively connected to the second signal terminal 252, the fifth signal terminal 255, the sixth signal terminal 256, the seventh signal terminal 257, and the eighth signal terminal 258 by the bonding wires 180.

In the current sensor 200 according to Preferred Embodiment 2 of the present invention, the magnetic field detection characteristics of the first magnetic sensor 120 and the second magnetic sensor 130 can be stabilized while improving the dielectric strength characteristics of the current sensor 200.

Preferred Embodiment 3

Hereafter, a current sensor according to Preferred Embodiment 3 of the present invention will be described with reference to the drawings. The current sensor according to

Preferred Embodiment 3 of the present invention differs from the current sensor 100 according to Preferred Embodiment 1 of the present invention mainly in terms of the arrangement of the support and the connection terminals, and therefore description of the elements or features of the configurations that are the same or substantially the same as the current sensor 100 according to Preferred Embodiment 1 of the present invention will not be repeated.

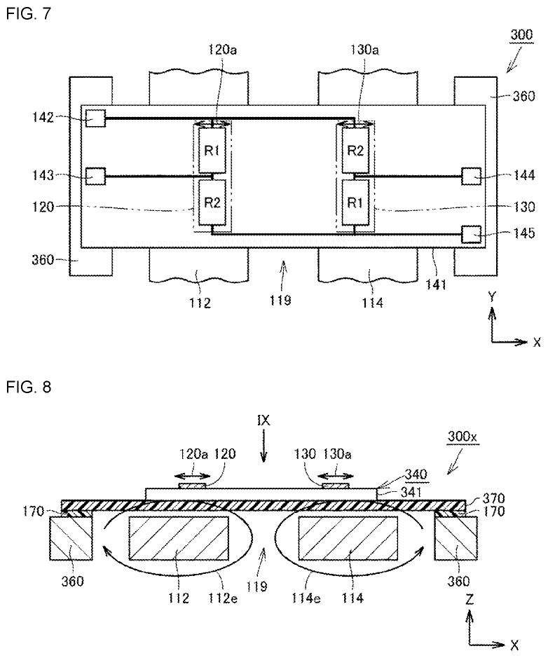

FIG. 6 is a sectional view illustrating the configuration of the current sensor according to Preferred Embodiment 3 of the present invention. FIG. 7 is a plan view in which the current sensor in FIG. 6 is viewed in the direction of arrow VII. FIG. 6 is the same sectional view as FIG. 2. The sealing resin is not illustrated in FIGS. 6 and 7.

As illustrated in FIGS. 6 and 7, in a current sensor 300 according to Preferred Embodiment 3 of the present invention, a support 360 is disposed outside a pair of opposing portions, namely, the second current path portion 112 and the fourth current path portion 114, so that the pair of opposing portions is disposed between portions of the support 360. Specifically, a portion of the support 360 is disposed on the opposite side of the second current path portion 112 from the fourth current path portion 114. Another portion of the support 360 is disposed on the opposite side of the fourth current path portion 114 from the second current path portion 112. The above-described portion of the support 360 and the above-described other portion of the support 360 are defined by a single member. In the current sensor 300 according to Preferred Embodiment 3 of the present invention, the support 360 is defined by a single member, but the support 360 may instead include two members, with one member of the support 360 being disposed on the other side in the X-axis direction with respect to a third current path portion 413 and the other member of the support 360 being disposed on the one side in the X-axis direction with respect to the third current path portion 413.

The first connection terminal 142 and the second connection terminal 143 are disposed at positions overlapping the above-described portion of the support 360 when viewed in the Z-axis direction, which is the direction in which the magnetic sensor chip 140 and the support 360 are arrayed. The third connection terminal 144 and the fourth connection terminal 145 are disposed at positions overlapping the above-described other portion of the support 360 when looking in the Z-axis direction, which is the direction in which the magnetic sensor chip 140 and the support 360 are arrayed.

In the current sensor 300 according to Preferred Embodiment 3 of the present invention, the magnetic sensor chip 140 is supported by the support 360 at both ends in the length direction of the magnetic sensor chip 140, and therefore the magnetic sensor chip 140 can be stably supported.

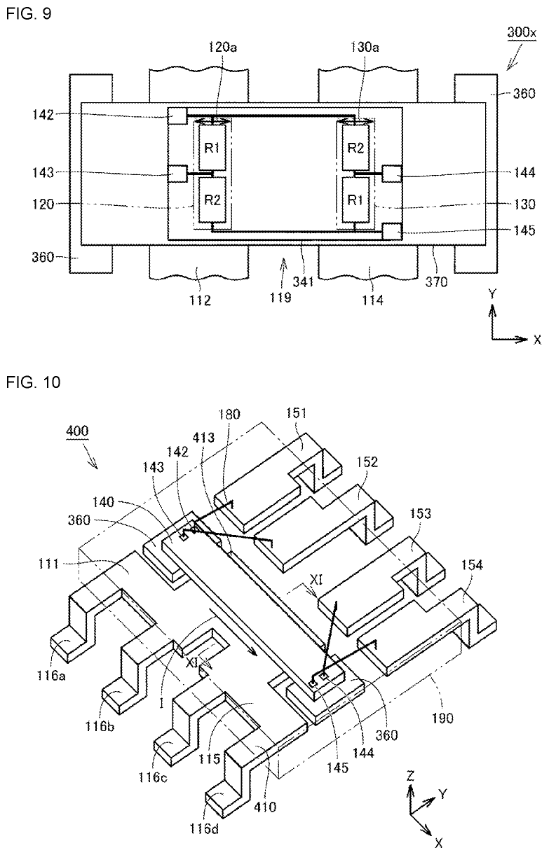

Next, a current sensor according to a modification of Preferred Embodiment 3 of the present invention will be described. FIG. 8 is a sectional view illustrating the configuration of the current sensor according to the modification of Preferred Embodiment 3 of the present invention. FIG. 9 is a plan view in which the current sensor in FIG. 7 is viewed in the direction of arrow IX. FIG. 8 is the same sectional view as FIG. 6. The sealing resin is not illustrated in FIGS. 8 and 9.

As illustrated in FIGS. 8 and 9, a current sensor 300x according to the modification of Preferred Embodiment 3 of the present invention includes a current path 110, a magnetic sensor chip 340, a plurality of signal terminals, a support 360, and an insulating member 370.

The magnetic sensor chip 340 includes at least one magnetic sensor including a magneto-resistance element and detects the strength of a magnetic field generated by a current I flowing along the current path 110 and includes a plurality of connection terminals that are electrically connected to the at least one magnetic sensor.

In the current sensor 300x according to the modification of Preferred Embodiment 3 of the present invention, the magnetic sensor chip 340 includes the first magnetic sensor 120 and the second magnetic sensor 130 as the at least one magnetic sensor. The magnetic sensor chip 340 includes a substrate 341. The first magnetic sensor 120 and the second magnetic sensor 130 are provided on the substrate 341. The substrate 341 is smaller than the substrate 141 in Preferred Embodiments 1 to 3. The substrate 341 is made of silicon, for example. However, the material of the substrate 341 does not have to be silicon and may instead be another semiconductor or an insulator, for example.

In the current sensor 300x according to the modification of Preferred Embodiment 3 of the present invention, the magnetic sensor chip 340 is supported by the support 360 with the insulating member 370 therebetween. The surface of the support 360 on the one side in the Z-axis direction and the surface of the insulating member 370 on the other side in the Z-axis direction are connected to each other by the die attach film 170. The substrate 341 is fixed to the surface of the insulating member 370 on the one side in the Z-axis direction. The insulating member 370 is made of, for example, an alumina substrate, polyimide tape, or the like.

As illustrated in FIG. 9, in the current sensor 300x according to the modification of Preferred Embodiment 3 of the present invention, the first connection terminal 142, the second connection terminal 143, the third connection terminal 144, and the fourth connection terminal 145 are disposed at positions overlapping the current path 110 when looking in the Z-axis direction, which is the direction in which the magnetic sensor chip 340 and the support 360 are arrayed. Specifically, when viewed in the Z-axis direction, the first connection terminal 142 and the second connection terminal 143 are disposed at positions overlapping the second current path portion 112 and the third connection terminal 144 and the fourth connection terminal 145 are disposed at positions overlapping the fourth current path portion 114.

In the current sensor 300x according to the modification of Preferred Embodiment 3 of the present invention, the magnetic sensor chip 340 can be reduced in size, and additionally, the generation of surface discharge between the current path 110 and the magnetic sensor chip 340 can be reduced or prevented and the dielectric strength characteristics of the current sensor 300x can be improved due to the magnetic sensor chip 340 being supported by the support 360 with the insulating member 370 therebetween.

Preferred Embodiment 4

Hereafter, a current sensor according to Preferred Embodiment 4 of the present invention will be described with reference to the drawings. The current sensor according to Preferred Embodiment 4 of the present invention differs from the current sensor 100 according to Preferred Embodiment 1 of the present invention mainly in terms of the shape of the current path and the arrangement of the support and the connection terminals, and therefore description of the portions of the configuration that are the same or substantially the same as the current sensor 100 according to Preferred Embodiment 1 of the present invention will not be repeated.

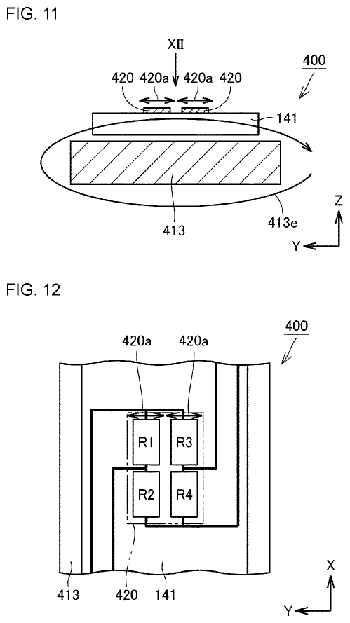

FIG. 10 is a perspective view illustrating the configuration of the current sensor according to Preferred Embodiment 4 of the present invention. FIG. 11 is a sectional view in which the current sensor in FIG. 10 is viewed in the direction of arrows XI-XI. FIG. 12 is a plan view in which the current sensor in FIG. 11 is viewed in the direction of arrow XII. In FIG. 10, sealing resin is illustrated in a see-through manner. The sealing resin is not illustrated in FIGS. 11 and 12.

As illustrated in FIGS. 10 to 12, a current sensor 400 according to Preferred Embodiment 4 of the present invention includes a current path 410, a magnetic sensor chip 140, a plurality of signal terminals, and a support 360.

The current path 410 includes a first current path portion 111 that extends towards the one side in the X-axis direction, a third current path portion 413 that extends towards the one side in the X-axis direction from a portion, on the one side in the Y-axis direction, of the end portion of the first current path portion 111 on the one side in the X-axis direction, and a fifth current path portion 115 that extends towards the one side in the X-axis direction from a portion, on the other side in the Y-axis direction, of the end portion of the third current path portion 413 on the one side in the X-axis direction. The first current path portion 111, the third current path portion 413, and the fifth current path portion 115 are embedded in the sealing resin 190.

The support 360 is disposed outside the third current path portion 413 in the X-axis direction so that the third current path portion 413 is interposed between portions of the support 360. Specifically, the support 360 includes two members, and one member of the support 360 is disposed on the other side in the X-axis direction with respect to the third current path portion 413. The other member of the support 360 is disposed on the one side in the X-axis direction with respect to the third current path portion 413. The support 360 includes two members in the current sensor 400 according to Preferred Embodiment 4 of the present invention, but a portion of the support 360 that is disposed on the other side in the X-axis direction with respect to the third current path portion 413 and a portion of the support 360 disposed on the one side in the X-axis direction with respect to the third current path portion 413 may instead be provided as a single member.

In the current sensor 400 according to Preferred Embodiment 4 of the present invention, as illustrated in FIGS. 11 and 12, the magnetic sensor chip 140 includes a first magnetic sensor 420 as the at least one magnetic sensor. The first magnetic sensor 420 is provided on the substrate 141. The number of magnetic sensors in Preferred Embodiment 4 of the present invention is not limited to one and instead there may be a plurality of magnetic sensors.

As illustrated in FIGS. 11 and 12, a magnetic sensitivity axis 420a of the first magnetic sensor 420 extends along the Y-axis direction. As illustrated in FIG. 12, the first magnetic sensor 420 includes a Wheatstone bridge circuit including a magneto-sensitive resistance R1, a fixed resistance R2, a fixed resistance R3, and a magneto-sensitive resistance R4. The resistance values of the magneto-sensitive resistance R1 and the magneto-sensitive resistance R4 change when a magnetic field is applied along the X-axis direction, whereas the resistance values of the fixed resistance R2 and the fixed resistance R3 negligibly change even when a magnetic field is applied along the X-axis direction. The magneto-sensitive resistance R4 is configured so that the phase of the output thereof is opposite to that of the magneto-sensitive resistance R1. The fixed resistance R3 has the same or substantially the same configuration as the fixed resistance R2.

As illustrated in FIG. 11, when the magnetic sensor chip 140 is supported by the support 360, the surface of the substrate 141 on the other side in the Z-axis direction and the surface of the third current path portion 413 on the one side in the Z-axis direction are separated from each other.

As illustrated in FIG. 12, the first magnetic sensor 420 is disposed at a position overlapping the third current path portion 413 when viewed in the Z-axis direction, which is the direction in which the magnetic sensor chip 140 and the support 360 are arrayed.

With this arrangement, when the current I flows along the current path 410, as illustrated in FIG. 11, a magnetic field 413e generated around the third current path portion 413 acts on the first magnetic sensor 420 in a direction along the magnetic sensitivity axis 420a.

In the current sensor 400 according to Preferred Embodiment 4 of the present invention, the first magnetic sensor 420 is disposed at a position overlapping the third current path portion 413 when looking in the Z-axis direction, which is the direction in which the magnetic sensor chip 140 and the support 360 are arrayed.

Thus, the magnetic field 413e generated around the third current path portion 413 acts on the first magnetic sensor 420 in a direction along the magnetic sensitivity axis 420a. As a result, the current I that is to be measured flowing along the current path 410 can be detected with high sensitivity by the first magnetic sensor 420.

In the current sensor 400 according to Preferred Embodiment 4 of the present invention, the magnetic field detection characteristics of the first magnetic sensor 420 can be stabilized while improving the dielectric strength characteristics of the current sensor 400.

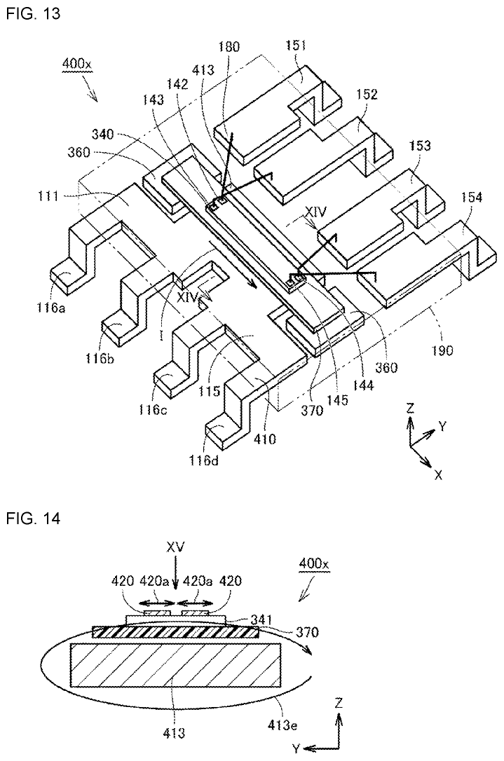

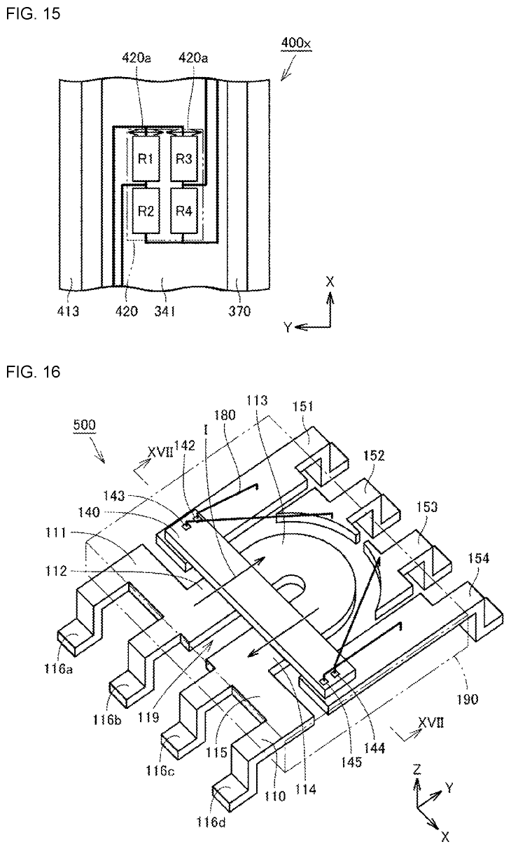

Next, a current sensor according to a modification of Preferred Embodiment 4 of the present invention will be described. FIG. 13 is a perspective view illustrating the configuration of a current sensor according to a modification of Preferred Embodiment 4 of the present invention. FIG. 14 is a sectional view in which the current sensor in FIG. 13 is viewed in the direction of arrows XIV-XIV. FIG. 15 is a plan view in which the current sensor in FIG. 14 is viewed in the direction of arrow XV. In FIG. 13, sealing resin is illustrated in a see-through manner. The sealing resin is not illustrated in FIGS. 14 and 15.

As illustrated in FIGS. 13 and 15, a current sensor 400x according to the modification of Preferred Embodiment 4 of the present invention includes a current path 410, a magnetic sensor chip 340, a plurality of signal terminals, a support 360, and an insulating member 370. The magnetic sensor chip 340 is supported by the support 360 with the insulating member 370 therebetween.

In the current sensor 400x according to the modification of Preferred Embodiment 4 of the present invention, the magnetic sensor chip 340 includes the first magnetic sensor 420 as the at least one magnetic sensor. The magnetic sensor chip 340 includes a substrate 341. The first magnetic sensor 420 is provided on the substrate 341.

As illustrated in FIG. 13, in the current sensor 400x according to the modification of Preferred Embodiment 4 of the present invention, the first connection terminal 142, the second connection terminal 143, the third connection terminal 144, and the fourth connection terminal 145 are disposed at positions overlapping the current path 410 when viewed in the Z-axis direction, which is the direction in which the magnetic sensor chip 340 and the support 360 are arrayed. Specifically, when viewed in the Z-axis direction, the first connection terminal 142, the second connection terminal 143, the third connection terminal 144, and the fourth connection terminal 145 are disposed at positions overlapping the third current path portion 413.

In the current sensor 400x according to the modification of Preferred Embodiment 4 of the present invention, the magnetic sensor chip 340 can be reduced in size, and additionally, the generation of surface discharge between the current path 410 and the magnetic sensor chip 340 can be reduced or prevented and the dielectric strength characteristics of the current sensor 400x can be improved due to the magnetic sensor chip 340 being supported by the support 360 with the insulating member 370 therebetween.

A current sensor according to Preferred Embodiment 5 of the present invention will be described with reference to the drawings. The current sensor according to Preferred Embodiment 5 of the present invention differs from the current sensor 100 according to Preferred Embodiment 1 of the present invention mainly in that signal terminals support a magnetic sensor chip, and therefore description of the portions of the configuration that are the same or substantially the same as the current sensor 100 according to Preferred Embodiment 1 of the present invention will not be repeated.

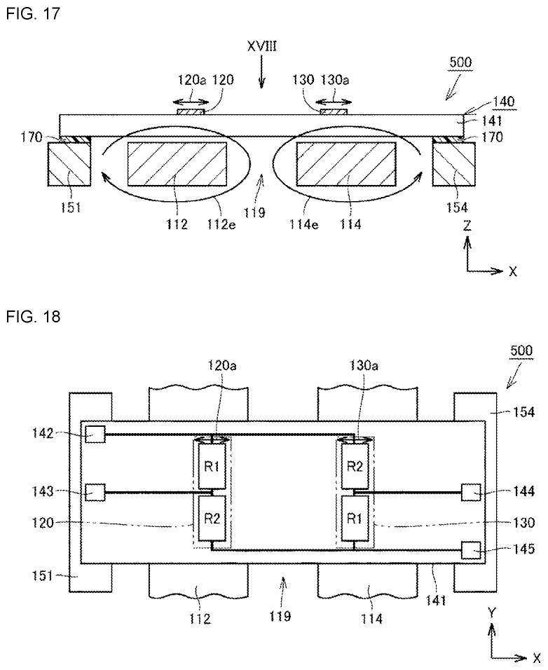

FIG. 16 is a perspective view illustrating the configuration of the current sensor according to Preferred Embodiment 5 of the present invention. FIG. 17 is a sectional view in which the current sensor in FIG. 16 is viewed in the direction of arrows XVII-XVII. FIG. 18 is a plan view in which the current sensor in FIG. 17 is viewed in the direction of arrow XVIII. In FIG. 16, sealing resin is illustrated in a see-through manner. The sealing resin is not illustrated in FIGS. 17 and 18.

As illustrated in FIGS. 16 to 18, in a current sensor 500 according to Preferred Embodiment 5 of the present invention, two signal terminals among a plurality of signal terminals support a magnetic sensor chip 140. Specifically, a first signal terminal 151 and a fourth signal terminal 154 support the magnetic sensor chip 140. In other words, the first signal terminal 151 and the fourth signal terminal 154 also define and function as supports.

The first magnetic sensor 120 is disposed at a position overlapping the second current path portion 112 when viewed the Z-axis direction, which is the direction in which the first signal terminal 151 and the fourth signal terminal 154 and the magnetic sensor chip 140 are arrayed. The second magnetic sensor 130 is disposed at a position overlapping the fourth current path portion 114 when viewed in the Z-axis direction, which is the direction in which the first signal terminal 151 and the fourth signal terminal 154 and the magnetic sensor chip 140 are arrayed.

In the current sensor 500 according to Preferred Embodiment 5 of the present invention, there is no need for a space in which to separately provide a support, and therefore the magnetic sensor chip 140 can be reduced in size.

In the current sensor 500 according to Preferred Embodiment 5 of the present invention, the magnetic field detection characteristics of the first magnetic sensor 120 and the second magnetic sensor 130 can be stabilized while improving the dielectric strength characteristics of the current sensor 500.

The current sensors according to the above-described preferred embodiments may be open loop current sensors or closed loop current sensors.

In the above description of the preferred embodiments, configurations that can be combined with each other may be combined with each other.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A current sensor comprising:
a current path along which a current to be measured flows;
a magnetic sensor chip including at least one magnetic sensor including a magneto-resistance element and a plurality of connection terminals electrically connected to the at least one magnetic sensor;
a plurality of signal terminals spaced apart from the current path and electrically connected to the plurality of connection terminals by bonding wires; and
a support spaced apart from the current path, at a different potential from the current path, and supporting the magnetic sensor chip; wherein
the at least one magnetic sensor is at a position overlapping the current path when viewed in a direction in which the magnetic sensor chip and the support are arrayed.

2. The current sensor according to claim 1, wherein
the at least one magnetic sensor includes a first magnetic sensor and a second magnetic sensor;
the current path includes a pair of opposing portions that are positioned with a gap therebetween and in which the current flows in opposite directions;
the first magnetic sensor is at a position overlapping one of the pair of opposing portions when viewed in the direction in which the magnetic sensor chip and the support are arrayed; and
the second magnetic sensor is at a position overlapping another one of the pair of opposing portions when viewed in the direction in which the magnetic sensor chip and the support are arrayed.

3. The current sensor according to claim 2, wherein the support is disposed in the gap.

4. The current sensor according to claim 1, wherein the at least one magnetic sensor includes a first magnetic sensor including a Wheatstone bridge circuit including two magneto-sensitive resistances.

5. The current sensor according to claim 2, wherein the support is outside the pair of opposing portions; and
the pair of opposing portions are interposed between portions of the support.

6. The current sensor according to claim 1, wherein the plurality of connection terminals are at positions overlapping the support when viewed in the direction in which the magnetic sensor chip and the support are arrayed.

7. The current sensor according to claim 1, wherein the plurality of connection terminals are at positions overlapping the current path when viewed in the direction in which the magnetic sensor chip and the support are arrayed.

8. The current sensor according to claim 1, wherein two signal terminals of the plurality of signal terminals define and function as the support.

9. The current sensor according to claim 1, wherein the current path includes a U-shaped folded-back portion.

10. The current sensor according to claim 1, further comprising:
a sealing resin; wherein
at least a portion of the current path is embedded in the sealing resin.

11. The current sensor according to claim 10, wherein the sealing resin includes epoxy resin.

12. The current sensor according to claim 10, wherein at least a portion of at least one of the plurality of signal terminals is embedded in the sealing resin.

13. The current sensor according to claim 12, wherein at least a portion of the at least one of the plurality of signal terminals is not embedded in the sealing resin.

14. The current sensor according to claim 1, wherein the current path is made of copper.

15. The current sensor according to claim 10, wherein the plurality of signal terminals are electrically insulated from the current path by the sealing resin.

16. The current sensor according to claim 1, wherein each of the plurality of signal terminals are made of copper.
